(19) United States
(12) Patent Application Publication
(10) Pub. No.: US 2024/0315037 A1
(43) Pub. Date: Sep. 19, 2024

(54) SEMICONDUCTOR DEVICE AND SEMICONDUCTOR DEVICE MANUFACTURING METHOD

(71) Applicant: Kioxia Corporation, Tokyo (JP)

(72) Inventors: Keita HASEGAWA, Yokkaichi (JP); Keisuke NAKATSUKA, Kobe (JP); Koichi SAKATA, Yokkaichi (JP)

(73) Assignee: Kioxia Corporation, Tokyo (JP)

(21) Appl. No.: 18/599,586

(22) Filed: Mar. 8, 2024

(30) Foreign Application Priority Data
Mar. 16, 2023 (JP) 2023-042220

(51) Int. Cl. H10B 43/35; H01L 23/522; H01L 23/528; H01L 25/065; H10B 41/10; H10B 41/27; H10B 41/35; H10B 41/41; H10B 41/50; H10B 43/10; H10B 43/27; H10B 43/40; H10B 43/50

(52) U.S. Cl. CPC H10B 43/35; H01L 23/5226; H01L 23/5283; H01L 25/0657; H10B 41/10; H10B 41/27; H10B 41/35; H10B 41/41; H10B 41/50; H10B 43/10; H10B 43/27; H10B 43/40; H10B 43/50; H01L 2225/06541

(57) ABSTRACT

A semiconductor device includes a first chip including a peripheral circuit, and a second chip bonded to the first chip. The second chip includes a stacked body, a contact, a first column-shaped part, a second conductive layer, and a second column-shaped part. The contact is connected to a staircase part of the stacked body. The first column-shaped part is formed to extend through a memory part of the stacked body in a first direction and forms a memory cell transistor at an intersection part with a first conductive layer. The second conductive layer is formed above the stacked body and connected to an upper end part of the first column-shaped part. The second column-shaped part is formed to extend through the staircase part in the first direction. The second column-shaped part is electrically insulated from the second conductive layer.

### CROSS-REFERENCE TO RELATED APPLICATION

This application is based upon and claims the benefit of priority from the prior Japanese Patent Applications No. 2023-42220, filed on Mar. 16, 2023, the entire contents of which are incorporated herein by reference.

### FIELD

Embodiments relate to a semiconductor device and a semiconductor device manufacturing method.

### BACKGROUND

In a semiconductor device manufacturing method, a first chip including a peripheral circuit and a second chip including an array structure of memory cell transistors are separately manufactured and then bonded together to manufacture a semiconductor device.

### BRIEF DESCRIPTION OF THE DRAWINGS

FIG. 1 is a block diagram illustrating a schematic configuration of a memory system of a first embodiment;

FIG. 2 is a block diagram illustrating a schematic configuration of a semiconductor device of the first embodiment;

FIG. 3 is a circuit diagram illustrating an equivalent circuit of the semiconductor device of the first embodiment;

FIG. 4 is a cross-sectional view illustrating a sectional structure of the semiconductor device of the first embodiment;

FIG. 5 is a cross-sectional view illustrating a sectional structure taken along line V-V of FIG. 4;

FIG. 6 is a cross-sectional view illustrating an enlarged sectional structure in the vicinity of a column-shaped part of the first embodiment;

FIG. 7 is a cross-sectional view illustrating an enlarged sectional structure in the vicinity of an upper end part of the column-shaped part of the first embodiment;

FIG. 8 is a cross-sectional view illustrating a sectional structure taken along line VIII-VIII of FIG. 4;

FIG. 9 is a cross-sectional view illustrating part of a process of manufacturing the semiconductor device of the first embodiment;

FIG. 10 is a cross-sectional view illustrating part of the process of manufacturing the semiconductor device of the first embodiment;

FIG. 11 is a cross-sectional view illustrating part of the process of manufacturing the semiconductor device of the first embodiment;

FIG. 12 is a cross-sectional view illustrating part of the process of manufacturing the semiconductor device of the first embodiment;

FIG. 13 is a cross-sectional view illustrating part of the process of manufacturing the semiconductor device of the first embodiment;

FIG. 14 is a cross-sectional view illustrating part of the process of manufacturing the semiconductor device of the first embodiment;

FIG. 15 is a cross-sectional view illustrating part of the process of manufacturing the semiconductor device of the first embodiment;

FIG. 16 is a cross-sectional view illustrating part of the process of manufacturing the semiconductor device of the first embodiment;

FIG. 17 is a cross-sectional view illustrating part of the process of manufacturing the semiconductor device of the first embodiment;

FIG. 18 is a cross-sectional view illustrating part of the process of manufacturing the semiconductor device of the first embodiment;

FIG. 19 is a cross-sectional view illustrating part of the process of manufacturing the semiconductor device of the first embodiment;

FIG. 20 is a cross-sectional view illustrating a sectional structure of a semiconductor device of a comparative example;

FIG. 21 is a cross-sectional view illustrating a sectional structure of a semiconductor device of a second embodiment;

FIG. 22 is a cross-sectional view illustrating part of a process of manufacturing the semiconductor device of the second embodiment;

FIG. 23 is a cross-sectional view illustrating part of the process of manufacturing the semiconductor device of the second embodiment;

FIG. 24 is a cross-sectional view illustrating part of the process of manufacturing the semiconductor device of the second embodiment;

FIG. 25 is a cross-sectional view illustrating part of the process of manufacturing the semiconductor device of the second embodiment;

FIG. 26 is a cross-sectional view illustrating part of the process of manufacturing the semiconductor device of the second embodiment;

FIG. 27 is a cross-sectional view illustrating part of the process of manufacturing the semiconductor device of the second embodiment;

FIG. 28 is a cross-sectional view illustrating part of the process of manufacturing the semiconductor device of the second embodiment;

FIG. 29 is a cross-sectional view illustrating part of the process of manufacturing the semiconductor device of the second embodiment;

FIG. 30 is a cross-sectional view illustrating a sectional structure of a semiconductor device of a third embodiment;

FIG. 31 is a cross-sectional view illustrating part of a process of manufacturing the semiconductor device of the third embodiment;

FIG. 32 is a cross-sectional view illustrating part of the process of manufacturing the semiconductor device of the third embodiment;

FIG. 33 is a cross-sectional view illustrating part of the process of manufacturing the semiconductor device of the third embodiment;

FIG. 34 is a cross-sectional view illustrating part of the process of manufacturing the semiconductor device of the third embodiment;

FIG. 35 is a cross-sectional view illustrating part of the process of manufacturing the semiconductor device of the third embodiment;

FIG. 36 is a cross-sectional view illustrating part of the process of manufacturing the semiconductor device of the third embodiment; and

FIG. 37 is a cross-sectional view illustrating part of the process of manufacturing the semiconductor device of the third embodiment.

### DETAILED DESCRIPTION

Embodiments will be described below with reference to the accompanying drawings. To facilitate understanding of description, the same component in the drawings is denoted by the same reference sign as much as possible and duplicate description thereof is omitted.

### 1 First Embodiment

A semiconductor device of a first embodiment will be described below. The semiconductor device according to the present embodiment is a non-volatile storage device configured as a NAND flash memory.

### 1.1 Configuration of Memory System

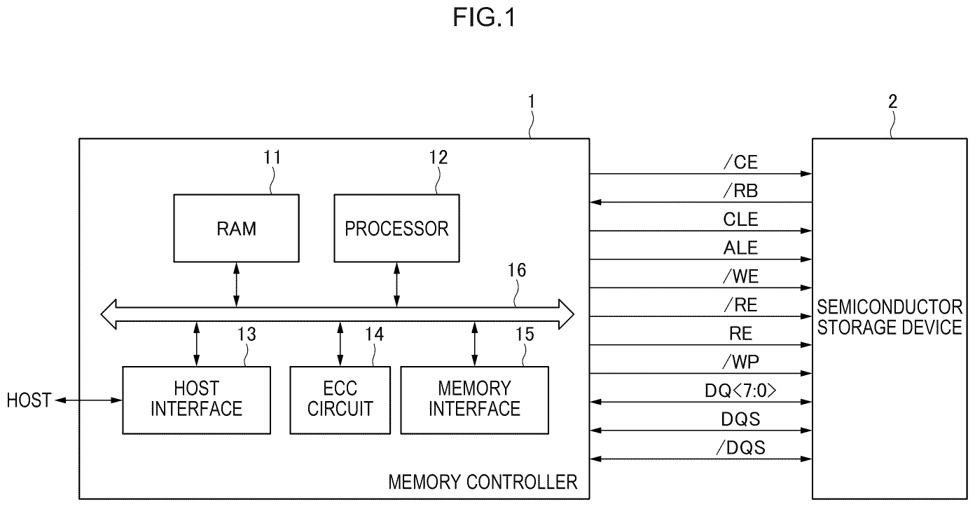

As illustrated in FIG. 1, a memory system of the present embodiment includes a memory controller 1 and a semiconductor device 2 (semiconductor storage device). The semiconductor device 2 is a non-volatile storage device configured as a NAND flash memory. The memory system can be connected to a host. The host is an electronic device such as a personal computer or a portable terminal. Note that although only one semiconductor device 2 is illustrated in FIG. 1, a plurality of semiconductor devices 2 are provided in the actual memory system.

The memory controller 1 controls data writing to the semiconductor device 2 in accordance with a writing request from the host. The memory controller 1 also controls data reading from the semiconductor device 2 in accordance with a reading request from the host.

Signals such as a chip enable signal /CE, a ready busy signal /RB, a command latch enable signal CLE, an address latch enable signal ALE, a write enable signal /WE, read enable signals RE and /RE, a write protect signal /WP, data signals DQ<7:0>, and data strobe signals DQS and /DQS are transmitted and received between the memory controller 1 and the semiconductor device 2.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to each other through an internal bus 16.

The host interface 13 outputs a request, user data (writing data), and the like received from the host to the internal bus 16. The host interface 13 transmits user data read from the semiconductor device 2, a response from the processor 12, and the like to the host.

The memory interface 15 controls, based on an instruction from the processor 12, processing of writing user data or the like to the semiconductor device 2 and processing of reading user data or the like from the semiconductor device 2.

The processor 12 collectively controls the memory controller 1. The processor 12 is, for example, a CPU or an MPU. When having received a request from the host through the host interface 13, the processor 12 performs control in accordance with the request.

The processor 12 determines a storage region (memory region) on the semiconductor device 2 for user data accumulated in the RAM 11. User data is stored in the RAM 11 through the internal bus 16. The processor 12 determines the memory region for data in a page unit (page data) that is the unit of writing. In the following description, user data stored in one page of the semiconductor device 2 is also referred to as “unit data”. Unit data is typically encoded and stored in the semiconductor device 2 as a codeword.

The processor 12 determines a memory region on the semiconductor device 2 as a writing destination for each unit data. A physical address is allocated to each memory region on the semiconductor device 2. The processor 12 manages, with the physical address, a memory region as a writing destination of unit data. The processor 12 designates the determined memory region (physical address) and instructs the memory interface 15 to write user data to the semiconductor device 2. The processor 12 manages correspondence between a logical address (logical address managed by the host) and a physical address of user data. When having received a reading request including a logical address from the host, the processor 12 specifies a physical address corresponding to the logical address, designates the physical address, and instructs the memory interface 15 to read user data.

The ECC circuit 14 encodes user data stored in the RAM 11 and generates a codeword. The ECC circuit 14 decodes a codeword read from the semiconductor device 2.

The RAM 11 temporarily stores user data received from the host before the user data is stored in the semiconductor device 2 and temporarily stores data read from the semiconductor device 2 before the data is transmitted to the host. The RAM 11 is a general-purpose memory such as an SRAM or a DRAM.

When having received a writing request from the host, the memory system in FIG. 1 operates as follows. The processor 12 temporarily stores target writing data in the RAM 11. The processor 12 reads the data stored in the RAM 11 and inputs the data to the ECC circuit 14. The ECC circuit 14 encodes the input data and inputs a codeword to the memory interface 15. The memory interface 15 writes the input codeword to the semiconductor device 2.

When having received a reading request from the host, the memory system in FIG. 1 operates as follows. The memory interface 15 inputs a codeword read from the semiconductor device 2 to the ECC circuit 14. The ECC circuit 14 decodes the input codeword and stores decoded data in the RAM 11. The processor 12 transmits the data stored in the RAM 11 to the host through the host interface 13.

### 1.2 Configuration of Semiconductor Device

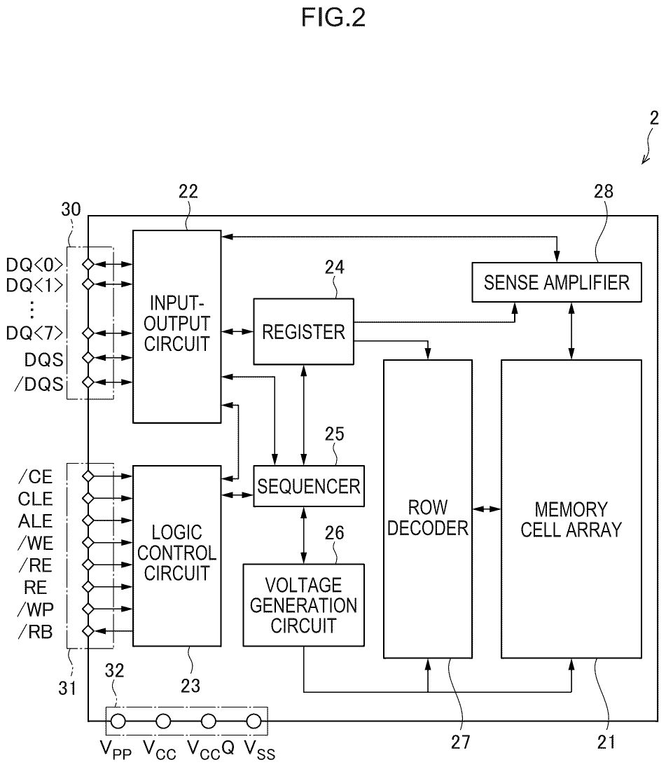

As illustrated in FIG. 2, the semiconductor device 2 includes a memory cell array 21, an input-output circuit 22, a logic control circuit 23, a register 24, a sequencer 25, a voltage generation circuit 26, a row decoder 27, a sense amplifier 28, an input-output pad group 30, a logic control pad group 31, and a power source input terminal group 32.

The memory cell array 21 is a part in which data is stored. The memory cell array 21 includes an array structure of a plurality of memory cell transistors associated with a plurality of bit lines and a plurality of word lines.

The input-output circuit 22 transmits and receives the signals DQ<7:0> and the data strobe signals DQS and /DQS to and from the memory controller 1. In addition, the input-output circuit 22 transfers commands and addresses in the signals DQ<7:0> to the register 24. Moreover, the input-output circuit 22 transmits and receives writing data and reading data to and from the sense amplifier 28.

The logic control circuit 23 receives the chip enable signal /CE, the command latch enable signal CLE, the address latch enable signal ALE, the write enable signal /WE, the read enable signals RE and /RE, and the write protect signal from the memory controller 1. In addition, the logic control circuit 23 transfers the ready busy signal /RB to the memory controller 1 and externally notifies the state of the semiconductor device 2.

The register 24 temporarily holds various types of data. For example, the register 24 holds a command that instructs writing operation, reading operation, erasing operation, or the like. The command is input to the input-output circuit 22 from the memory controller 1 and then transferred from the input-output circuit 22 to the register 24 and held there. The register 24 also holds an address corresponding to the above-described command. The address is input to the input-output circuit 22 from the memory controller 1 and then transferred from the input-output circuit 22 to the register 24 and held there. In addition, the register 24 holds status information indicating the operation state of the semiconductor device 2. The status information is updated by the sequencer 25 each time when the operation state of the memory cell array 21 or the like is changed. The status information is output from the input-output circuit 22 to the memory controller 1 as a state signal in accordance with a request from the memory controller 1.

The sequencer 25 controls the operation of components including the memory cell array 21 based on control signals input to the input-output circuit 22 and the logic control circuit 23 from the memory controller 1.

The voltage generation circuit 26 is a part that generates voltage required for each of writing operation, reading operation, and erasing operation of data at the memory cell array 21. The voltage includes, for example, voltage applied to each of the plurality of word lines and the plurality of bit lines of the memory cell array 21. The operation of the voltage generation circuit 26 is controlled by the sequencer 25.

The row decoder 27 is a circuit constituted by switches for applying voltage to each of the plurality of word lines of the memory cell array 21. The row decoder 27 receives a block address and a row address from the register 24 and selects a block based on the block address and a word line based on the row address. The row decoder 27 switches the open and close state of the switches so that voltage from the voltage generation circuit 26 is applied to the selected word line. The operation of the row decoder 27 is controlled by the sequencer 25.

The sense amplifier 28 is a circuit for adjusting voltage applied to each bit line of the memory cell array 21 and for reading and converting voltage of the bit line into data. At the time of data reading, the sense amplifier 28 obtains data read from a memory cell transistor of the memory cell array 21 to a bit line and transfers the obtained reading data to the input-output circuit 22. At the time of data writing, the sense amplifier 28 transfers data written through a bit line to a memory cell transistor. The operation of the sense amplifier 28 is controlled by the sequencer 25.

The input-output pad group 30 is a part provided with a plurality of terminals (pads) for transmitting and receiving each signal between the memory controller 1 and the input-output circuit 22. The terminals are individually provided in a manner corresponding to the signals DQ<7:0> and the data strobe signals DQS and /DQS, respectively.

The logic control pad group 31 is a part provided with a plurality of terminals for transmitting and receiving each signal between the memory controller 1 and the logic control circuit 23. The terminals are individually provided in a manner corresponding to the chip enable signal /CE, the command latch enable signal CLE, the address latch enable signal ALE, the write enable signal /WE, the read enable signals RE and /RE, the write protect signal /WP, and the ready busy signal /RB, respectively.

The power source input terminal group 32 is a part provided with a plurality of terminals for receiving application of voltages required for the operation of the semiconductor device 2. The voltages applied to each terminal include power voltages Vcc, VccQ, Vpp and ground voltage Vss. The power voltage Vcc is circuit power voltage externally provided as an operation power source and is, for example, voltage of approximately 3.3 V. The power voltage VccQ is, for example, voltage of 1.2 V. The power voltage VccQ is voltage used to transmit and receive signals between the memory controller 1 and the semiconductor device 2. The power voltage Vpp is power voltage higher than the power voltage Vcc and is, for example, voltage of 12 V.

### 1.3 Electronic Circuit Configuration of Memory Cell Array

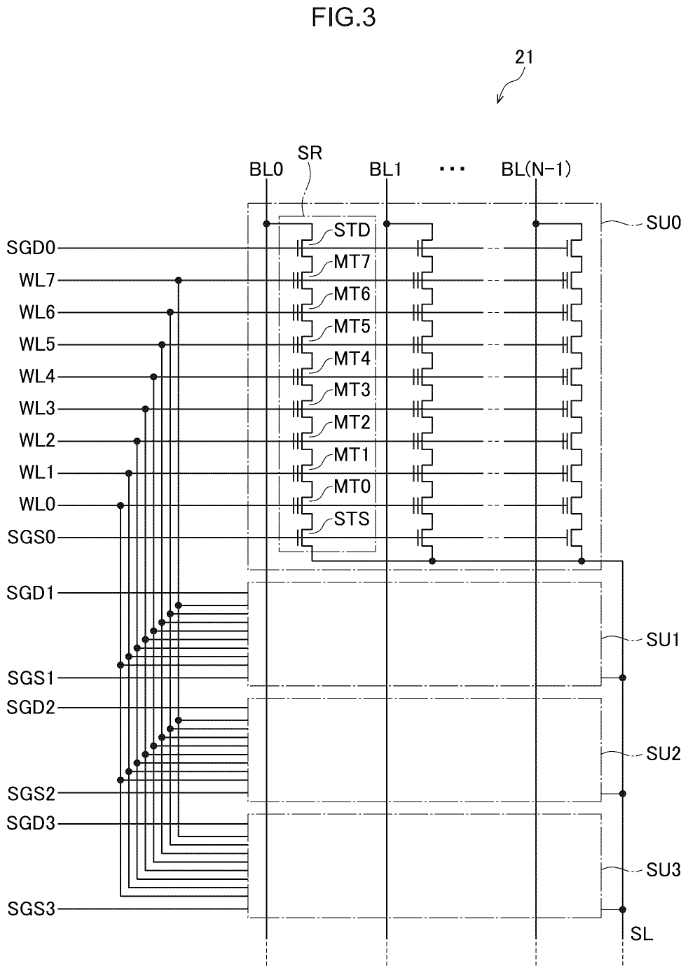

An electronic circuit configuration of the memory cell array 21 will be described below. As illustrated in FIG. 3, the memory cell array 21 includes a plurality of string units SU0 to SU3. Each of the string units SU0 to SU3 includes a plurality of NAND strings SR. Each NAND string SR includes, for example, eight memory cell transistors MT0 to MT7 and two select transistors STD and STS.

The plurality of string units SU0 to SU3 as a whole constitute one block. Note that although only one block is illustrated in FIG. 3, a plurality of such blocks are provided in the memory cell array 21 in reality.

In the following description, the string units SU0 to SU3 are also referred to as a “string unit SU” when not distinguished from one another. In addition, the memory cell transistors MT0 to MT7 are also referred to as a “memory cell transistor MT” when not distinguished from one another.

The memory cell array 21 includes N bit lines BL0 to BL(N−1). Note that the number “N” is a positive integer. Each string unit SU includes NAND strings SR in a number equal to the number N of the bit lines BL0 to BL(N−1). The memory cell transistors MT0 to MT7 provided in each NAND string SR are disposed in series between the source of the select transistor STD and the drain of the select transistor STS. The drain of the select transistor STD is connected to any of the plurality of bit lines BL0 to BL(N−1). The source of the select transistor STS is connected to a source line SL. In the following description, the bit lines BL0 to BL(N−1) are also referred to as a “bit line BL” when not distinguished from one another.

Each memory cell transistor MT is configured as a transistor including an electric charge accumulation film at a gate part. The amount of electric charge accumulated in the electric charge accumulation film corresponds to data held in the memory cell transistor MT.

Any gates of a plurality of select transistors STD provided in the string unit SU0 are connected to a select gate line SGD0. Voltage for switching opening and closing of each select transistor STD is applied to the select gate line SGD0. Similarly, the string units SU1 to SU3 are connected to select gate lines SGD1 to SGD3, respectively. In the following description, the select gate lines SGD1 to SGD3 are referred to as a “select gate line SGD” when not distinguished from one another.

Any gates of a plurality of select transistors STS provided in the string unit SU0 are connected to a select gate line SGS0. Voltage for switching opening and closing of each select transistor STS is applied to the select gate line SGS0. Similarly, the string units SU1 to SU3 are connected to select gate lines SGS1 to SGS3, respectively. In the following description, the select gate lines SGS1 to SGS3 are referred to as a “select gate line SGS” when not distinguished from one another.

The gates of the memory cell transistors MT0 to MT7 are connected to word lines WL0 to WL7, respectively. Voltage is applied to each of the word lines WL0 to WL7 in order to, for example, switch opening and closing of the memory cell transistors MT0 to MT7 and change the amount of electric charge accumulated in the electric charge accumulation film of each of the memory cell transistors MT0 to MT7.

Data writing and reading in the semiconductor device 2 are collectively performed for each unit referred to as “page” on a plurality of memory cell transistors MT connected to a word line WL in a string unit SU. Data erasing in the semiconductor device 2 is collectively performed on all memory cell transistors MT included in a block. Various methods that are publicly known can be employed as specific methods for performing such data writing, reading, and erasing, and thus detailed description thereof is omitted.

### 1.4 Structure of Semiconductor Device

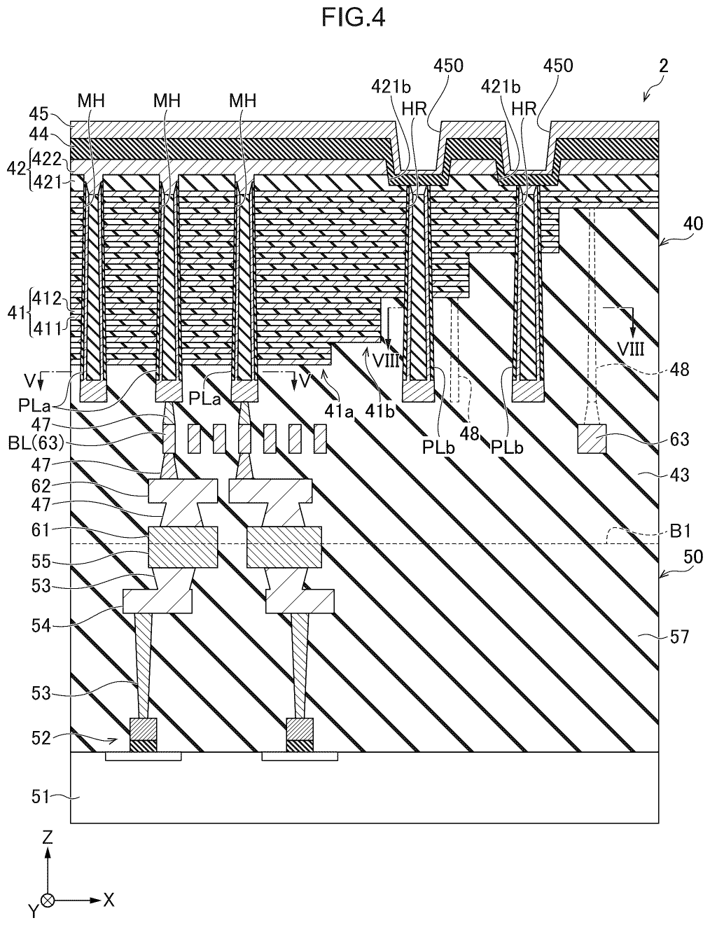

The following specifically describes the structure of the semiconductor device 2, in particular, in the vicinity of the memory cell array 21. As illustrated in FIG. 4, the semiconductor device 2 includes an array part 40 including a stacked body 41 of memory cell transistors, and a circuit part 50 including peripheral circuits. The peripheral circuits include the sense amplifier 28 and the row decoder 27 illustrated in FIG. 2. The array part 40 and the circuit part 50 are bonded together at a bonding surface B1 and electrically connected to each other through wires joined at the bonding surface B1. Accordingly, the semiconductor device 2 of the present embodiment has a CMOS bonding array (CBA) structure. In the present embodiment, the circuit part 50 corresponds to a first chip and the array part 40 corresponds to a second chip.

The circuit part 50 includes a substrate 51, a CMOS circuit 52, a via 53, wiring layers 54 and 55, and an interlayer insulating layer 57.

The substrate 51 is a semiconductor substrate such as a silicon substrate. The CMOS circuit 52 is constituted by transistors provided on the substrate 51. Semiconductor elements such as resistance elements and capacitor elements other than the CMOS circuit 52 may be formed on the substrate 51.

In the following description, directions parallel to the surface of the substrate 51 and orthogonal to each other are referred to as an X direction and a Y direction, and a direction orthogonal to the surface of the substrate 51 is referred to as a Z direction. The positive Z direction is referred to as an upper side, and the negative Z direction is referred to as a lower side. The Z direction may be or may not be aligned with the direction of gravity. In the present embodiment, the Z direction corresponds to a first direction.

The via 53 electrically connects the CMOS circuit 52 and the wiring layer 54 or electrically connects the wiring layer 54 and the wiring layer 55. The wiring layer 54 has a multi-layer wiring structure in the interlayer insulating layer 57. The wiring layer 55 is embedded in the interlayer insulating layer 57 and exposed substantially flush with the surface of the interlayer insulating layer 57. The wiring layers 54 and 55 are electrically connected to the CMOS circuit 52 or the like through the via 53. The via 53 and the wiring layers 54 and 55 are formed of a low-resistance metal such as copper or tungsten. The interlayer insulating layer 57 covers and protects the CMOS circuit 52, the via 53, the wiring layers 54 and 55, and the like. The interlayer insulating layer 57 is, for example, a silicon oxide (SiOx) layer.

The array part 40 includes the stacked body 41, column-shaped parts PLa and PLb, a source layer 42, an interlayer insulating layer 43, an insulating layer 44, and a conductive layer 45.

The stacked body 41 is provided above the CMOS circuit 52 in the circuit part 50 and positioned in the Z direction relative to the substrate 51. The stacked body 41 is constituted by a plurality of conductive layers 411 and insulating layers 412 alternately stacked in the Z direction. In the present embodiment, each conductive layer 411 corresponds to a first conductive layer, and each insulating layer 412 corresponds to a first insulating layer. One or more of conductive layers 411 at the upper and lower ends of the stacked body 41 in the Z direction function as, for example, a select gate line SGS on the source side and a select gate line SGD on the drain side. The select gate line SGS on the source side is provided on the upper region of the stacked body 41, and the select gate line SGD on the drain side is provided on the lower region of the stacked body 41. The conductive layers 411 disposed between the select gate line SGS on the source side and the select gate line SGD on the drain side function as word lines WL. The bit lines BL are disposed below the stacked body 41. The bit lines BL are formed to extend in the Y direction.

The stacked body 41 includes a memory part 41a and a staircase part 41b. The memory part 41a is a part in which the plurality of conductive layers 411 and the plurality of insulating layers 412 are alternately stacked in the Z direction. A plurality of memory cells are disposed in the memory part 41a. The staircase part 41b is a part formed in a stepped shape at an end part of the stacked body 41 in the X direction.

The source layer 42 is provided above the stacked body 41. The source layer 42 includes an insulating layer 421 and a conductive layer 422. The insulating layer 421 is provided above the stacked body 41. The insulating layer 421 is, for example, silicon oxide. The conductive layer 422 is provided above the insulating layer 421. The conductive layer 422 is formed of a metallic material such as tungsten. The conductive layer 422 functions as the source line SL illustrated in FIG. 3. In the present embodiment, the conductive layer 422 corresponds to a second conductive layer.

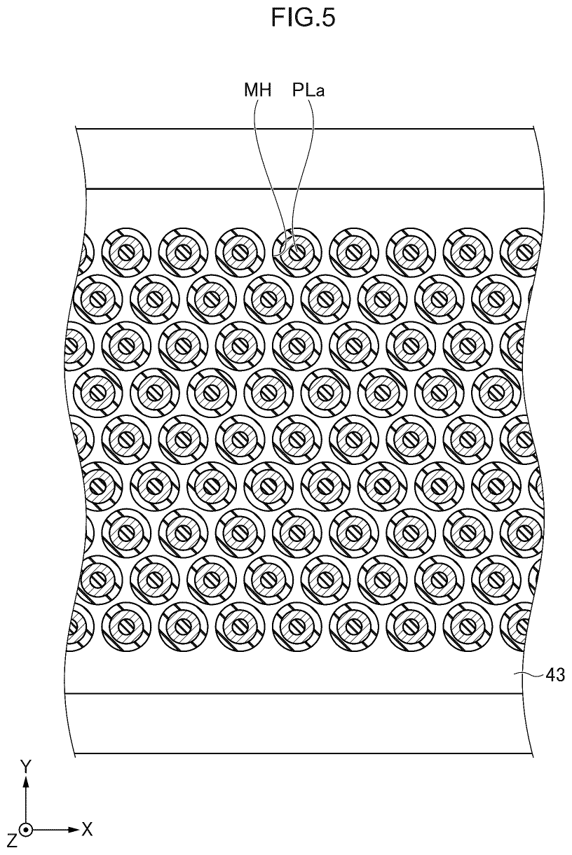

A plurality of memory holes MH are formed to penetrate in the Z direction in the memory part 41a of the stacked body 41. FIG. 5 illustrates a sectional structure taken along line V-V of FIG. 4. As illustrated in FIG. 5, the plurality of memory holes MH are disposed in a staggered shape when viewed from the Z direction. The column-shaped part PLa is provided inside each memory hole MH. Accordingly, the column-shaped part PLa is formed to extend through the memory part 41a in the Z direction.

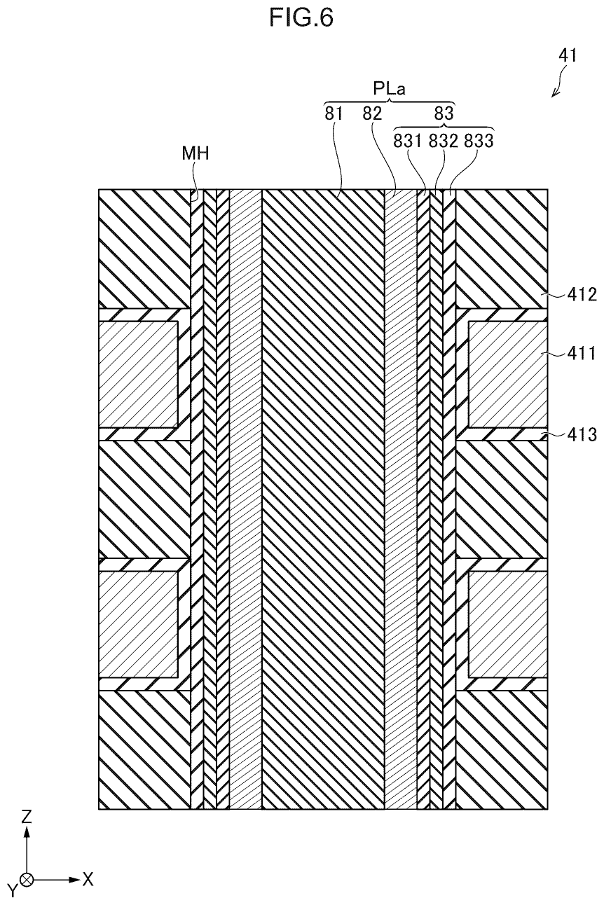

FIG. 6 illustrates an enlarged sectional structure in the vicinity of the column-shaped part PLa illustrated in FIG. 4. As illustrated in FIG. 6, the column-shaped part PLa has a circular or elliptical sectional shape. The column-shaped part PLa includes a core part 81, a semiconductor layer 82, and a gate insulating film 83.

The core part 81 is provided at a central part of the column-shaped part PLa and formed in a substantially cylindrical shape. The core part 81 is formed of an insulator such as silicon oxide. In the present embodiment, the core part 81 corresponds to a first core part.

The semiconductor layer 82 is formed in a substantially cylindrical shape and provided to enclose the outer periphery of the core part 81. The semiconductor layer 82 is formed of, for example, polysilicon (Poly-Si). The semiconductor layer 82 is a part in which channels of the memory cell transistors MT and the like are formed.

The gate insulating film 83 is formed in a substantially cylindrical shape and provided to enclose the outer periphery of the semiconductor layer 82. The gate insulating film 83 includes a tunnel insulating film 831, an electric charge accumulation film 832, and a block insulating film 833 that are stacked between the semiconductor layer 82 and each conductive layer 411.

The tunnel insulating film 831 is provided to cover the outer periphery of the semiconductor layer 82. The tunnel insulating film 831 is, for example, a silicon oxide film or a film containing silicon oxide and silicon nitride. The tunnel insulating film 831 functions as a potential barrier between the semiconductor layer 82 and the electric charge accumulation film 832. For example, in a case where electrons are injected into the electric charge accumulation film 832 from the semiconductor layer 82 (in a case of writing operation), the electrons pass (tunnel) through the potential barrier of the tunnel insulating film 831. In a case where holes are injected into the electric charge accumulation film 832 from the semiconductor layer 82 (in a case of erasing operation), the holes pass through the potential barrier of the tunnel insulating film 831.

The electric charge accumulation film 832 is provided to cover the outer periphery of the tunnel insulating film 831. The electric charge accumulation film 832 is, for example, a silicon nitride film. The electric charge accumulation film 832 includes trapping sites where electric charge is trapped in the film. A part of the electric charge accumulation film 832, which is sandwiched between each conductive layer 411 and the semiconductor layer 82 constitutes an electric charge accumulation film in which electric charge is accumulated, in other words, a storage region of a memory cell transistor MT.

The block insulating film 833 is provided to cover the outer periphery of the electric charge accumulation film 832. The block insulating film 833 is a film for preventing back tunneling of electric charge from each conductive layer 411 to the gate insulating film 83. The block insulating film 833 is, for example, a silicon oxide film or a metallic oxide film. The metallic oxide is, for example, aluminum oxide.

The outer periphery of each conductive layer 411 is covered by a barrier insulating film 413. For example, a stacked structure film of silicon nitride and titanium is selected as the barrier insulating film 413 in a case where the conductive layer 411 is formed of tungsten. An electric conductor film of titanium nitride or the like may be used in place of the barrier insulating film 413.

A part of the column-shaped part PLa, which is positioned on the inner side of each conductive layer 411, in other words, which intersects each conductive layer 411 functions as a transistor. Accordingly, in the column-shaped part PLa, a plurality of transistors are electrically connected in series in the longitudinal direction of the column-shaped part PLa. Each conductive layer 411 functions as the gate of each transistor. The semiconductor layer 82 functions as the channel of each transistor.

Some of the transistors arranged in series in the longitudinal direction of the column-shaped part PLa function as the plurality of memory cell transistors MT illustrated in FIG. 3. Transistors provided at the respective ends of the plurality of memory cell transistors MT arranged in series function as the select transistors STD and STS illustrated in FIG. 3, respectively.

As illustrated in FIG. 4, a lower end part of the column-shaped part PLa is electrically connected to a bit line BL through a via 47. An upper end part of the column-shaped part PLa is electrically connected to the conductive layer 422 of the source layer 42.

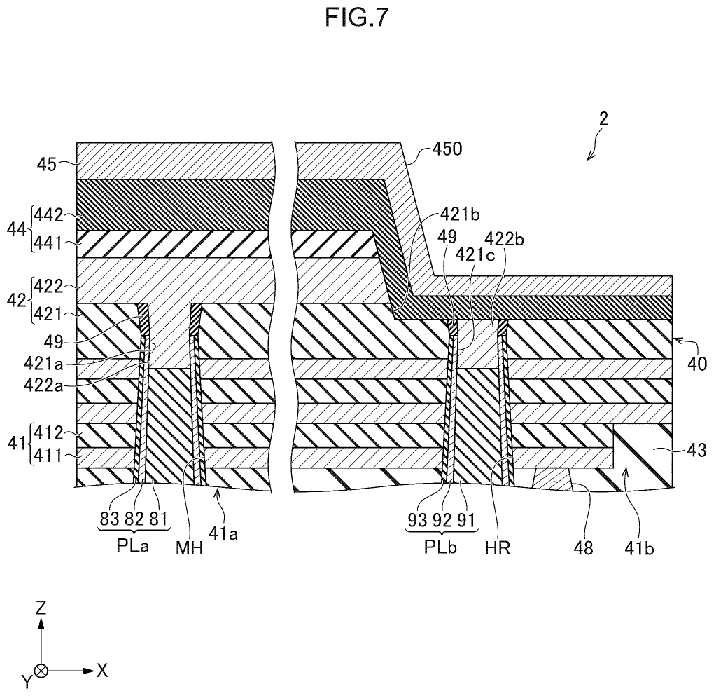

FIG. 7 illustrates an enlarged sectional structure in the vicinity of the upper end part of the column-shaped part PLa. As illustrated in FIG. 7, a hole 421a extending from the upper surface of the insulating layer 421 to the column-shaped part PLa is formed at a part of the insulating layer 421, which is positioned above the column-shaped part PLa. An insulating layer 49 is formed on the inner peripheral surface of the hole 421a. The insulating layer 49 is formed of, for example, highly crystalline silicon oxide. The hole 421a is formed to extend to the inside of the upper end part of the column-shaped part PLa by scraping an upper end part of the core part 81 of the column-shaped part PLa. The inner wall surface of a part of the hole 421a, which extends to the inside of the column-shaped part PLa is formed of the semiconductor layer 82 and the gate insulating film 83 in the column-shaped part PLa.

A protrusion part 422a extending to the inside of the upper end part of the column-shaped part PLa through the hole 421a formed through the insulating layer 421 is formed in the conductive layer 422. The protrusion part 422a of the conductive layer 422 is joined to the upper end surface of the core part 81 in the column-shaped part PLa and also joined to the inner peripheral surface of an upper end part of the semiconductor layer 82 in the column-shaped part PLa. A part where the inner peripheral surface of the semiconductor layer 82 in the column-shaped part PLa is joined to the protrusion part 422a of the conductive layer 422 forms Schottky junction. The semiconductor device 2 of the present embodiment has what is called a topside source line contact (TSC) structure in which the upper end part of the column-shaped part PLa is connected to the source line SL. In the present embodiment, the column-shaped part PLa corresponds to a first column-shaped part.

As illustrated in FIG. 4, the via 47 and wiring layers 61 to 63 are provided below the stacked body 41. The wiring layers 61 to 63 constitute a multi-layer wiring structure in the interlayer insulating layer 43. The bit lines BL are included in the wiring layer 63. The wiring layer 61 is embedded in the interlayer insulating layer 43 and exposed substantially flush with the surface of the interlayer insulating layer 43. The wiring layers 61 and 62 are electrically connected to the column-shaped part PLa through the via 47. The via 47 and the wiring layers 61 to 63 are formed of low-resistance metal such as copper or tungsten. The wiring layer 63 is electrically connected through a contact 48 to a part that functions as a word line WL in the staircase part 41b.

A plurality of column-shaped holes HR are formed to penetrate in the Z direction in the staircase part 41b of the stacked body 41. The column-shaped part PLb is provided inside each column-shaped hole HR. Accordingly, the column-shaped part PLb is formed to extend through the staircase part 41b in the Z direction. The column-shaped part PLb has the same structure as the column-shaped part PLa provided in the memory hole MH, in other words, the structure illustrated in FIG. 6, and thus detailed description of its shape is omitted. In the following description, as illustrated in FIG. 7, a core part of the column-shaped part PLb is denoted by reference sign 91, a semiconductor layer of the column-shaped part PLb is denoted by reference sign 92, and a gate insulating film of the column-shaped part PLb is denoted by reference sign 93. The column-shaped part PLb is provided not to form a memory cell transistor but to improve the strength of the staircase part 41b. The column-shaped part PLb is formed larger than the column-shaped part PLa. For example, the column-shaped part PLb has a diameter approximately 1.2 times larger than that of the column-shaped part PLa. In the present embodiment, the column-shaped part PLb corresponds to a second column-shaped part. The core part 91 of the column-shaped part PLb corresponds to the first core part.

As illustrated in FIG. 7, the conductive layer 422 is removed at a part positioned above the column-shaped part PLb. A recessed part 421b is formed at a part of the insulating layer 421, which is positioned above the column-shaped part PLb. A hole 421c extending to the column-shaped part PLb is formed at the bottom surface of the recessed part 421b. Similarly to the hole 421a, the insulating layer 49 is formed on the inner peripheral surface of the hole 421c. The hole 421a is formed to extend to the inside of an upper end part of the column-shaped part PLb by scraping an upper end part of the core part 91 of the column-shaped part PLb. The inner wall surface of a part of the hole 421a, which extends to the inside of the column-shaped part PLa is formed of the semiconductor layer 92 and the gate insulating film 93 of the column-shaped part PLb. A conductive layer 422b is embedded inside the hole 421a. The conductive layer 422b is part of the conductive layer 422, which is not removed but remains inside the hole 421a when the semiconductor device 2 is manufactured.

As illustrated in FIG. 4, the contact 48 and the wiring layer 63 are provided below the staircase part 41b of the stacked body 41. The wiring layer 63 is electrically connected to the staircase part 41b of the stacked body 41 through the contact 48. The contact 48 is formed of low-resistance metal such as copper or tungsten.

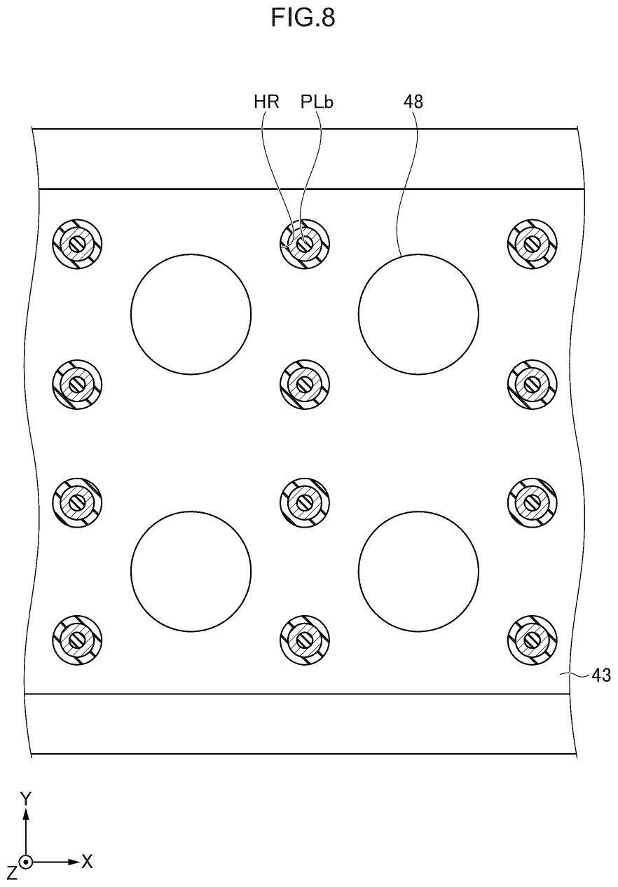

FIG. 8 illustrates a sectional structure taken along line VIII-VIII of FIG. 4. As illustrated in FIG. 8, the plurality of column-shaped holes HR are disposed in lines at a predetermined interval in the Y direction, and the column-shaped holes HR are disposed in lines at a predetermined interval in the X direction. The contact 48 is disposed between the lines of the column-shaped holes HR.

As illustrated in FIG. 4, the insulating layer 44 is provided above the source layer 42. The insulating layer 44 is, for example, a silicon oxide film or a silicon nitride (SiN) film. As illustrated in FIG. 7, the insulating layer 44 is constituted by insulating layers 441 and 442. The insulating layer 441 is provided above the conductive layer 422. The insulating layer 442 is provided above the insulating layer 441 and above the insulating layer 421 and above the column-shaped part PLb at a part where the conductive layer 422 is partially removed. In the present embodiment, the insulating layer 44 corresponds to a second insulating layer.

The conductive layer 45 is provided above the insulating layer 442. The conductive layer 45 is formed of a metallic material such as copper. Since the conductive layer 422 is removed around a part of the insulating layer 421 where the hole 421c is formed, the insulating layer 442 and the conductive layer 45 are formed in a recessed shape along the hole 421c. Accordingly, a recessed part 450 is formed at a part of the conductive layer 45, which is positioned above the column-shaped part PLb. The upper surface of each of the conductive layer 422 and the insulating layer 49 provided at the upper end part of the column-shaped part PLb is in contact with the insulating layer 44. In the present embodiment, the conductive layer 45 corresponds to a fourth conductive layer.

As illustrated in FIG. 4, in the semiconductor device 2, the interlayer insulating layer 43 in the array part 40 and the interlayer insulating layer 57 in the circuit part 50 are bonded together at the bonding surface B1, and the wiring layer 61 in the array part 40 and the wiring layer 55 in the circuit part 50 are joined together at the bonding surface B1. Accordingly, the array part 40 and the circuit part 50 are electrically connected through the wiring layers 61 and 55.

### 1.5 Semiconductor Device Manufacturing Method

The following describes a method of manufacturing the semiconductor device 2 of the present embodiment. In manufacturing of the semiconductor device 2, first, a first wafer corresponding to the array part 40 and a second wafer corresponding to the circuit part 50 are separately manufactured.

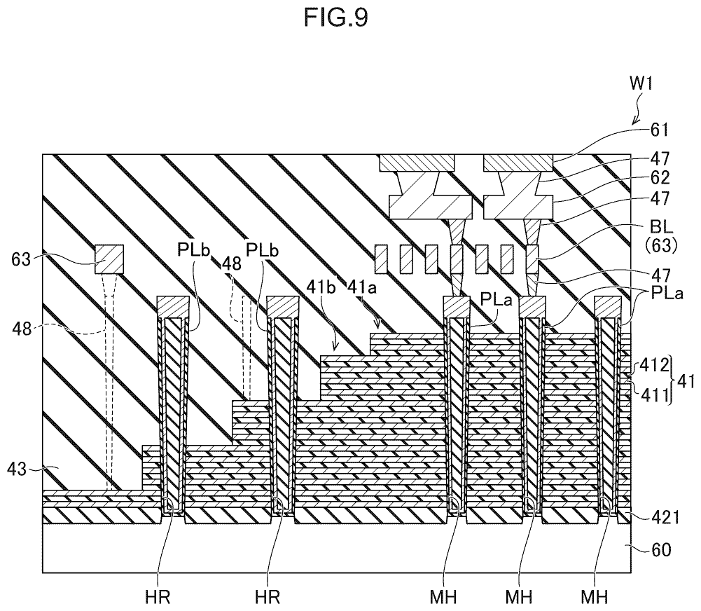

Specifically, as illustrated in FIG. 9, a first wafer W1 is manufactured by forming the insulating layer 421, the stacked body 41, the column-shaped parts PLa and PLb, the via 47, the wiring layers 61 to 63, the contacts 48, and the interlayer insulating layer 43 on a substrate 60. The gate insulating film 83 and the semiconductor layer 82 are stacked at a bottom part of the column-shaped part PLa. Similarly, the gate insulating film 93 and the semiconductor layer 92 are stacked at a bottom part of the column-shaped part PLb.

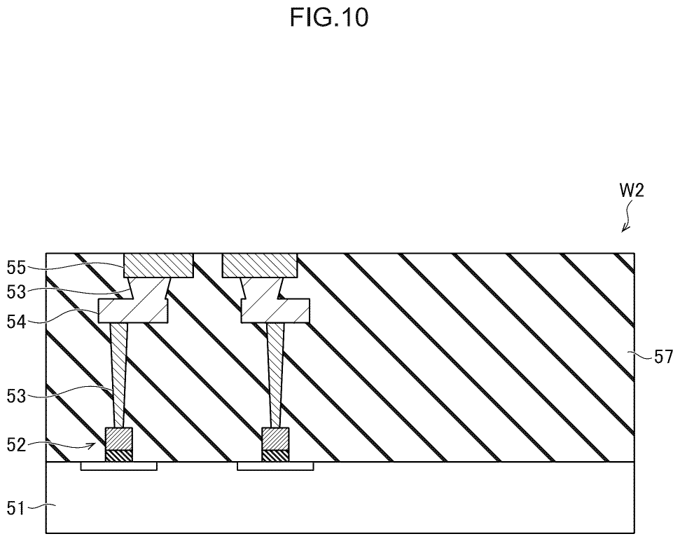

As illustrated in FIG. 10, a second wafer W2 is manufactured by forming the CMOS circuit 52, the via 53, the wiring layers 54 and 55, and the interlayer insulating layer 57 on the substrate 51.

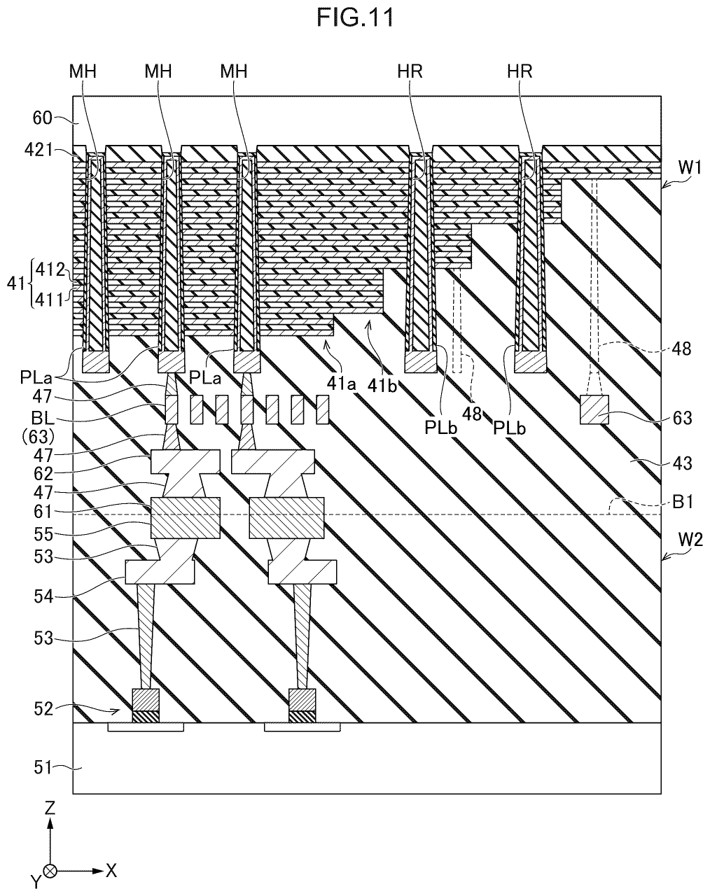

Subsequently, the first wafer W1 and the second wafer W2 are bonded together as illustrated in FIG. 11. In this bonding process, for example, the first wafer W1 is closely made contact with the second wafer W2 and then bonded through thermal treatment or the like. At this time, an exposed surface of the wiring layer 61 of the first wafer W1 and an exposed surface of the wiring layer 55 of the second wafer W2 are electrically joined together.

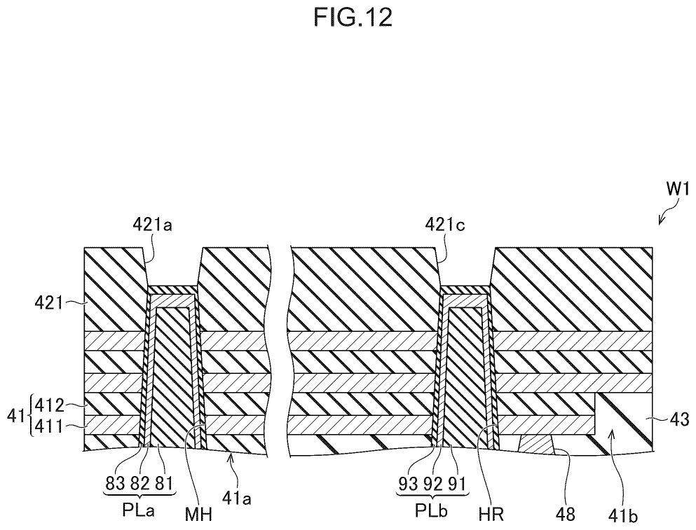

Subsequently, the substrate 60 of the first wafer W1 is removed by wet etching or the like as illustrated in FIG. 12. Accordingly, the insulating layer 421 is exposed at the upper surface of the first wafer W1. In addition, the upper end surface of the column-shaped part PLa, specifically, the gate insulating film 83 is exposed in the hole 421a of the insulating layer 421. Furthermore, the upper end surface of the column-shaped part PLb, specifically, the gate insulating film 93 is exposed in the hole 421c of the insulating layer 421.

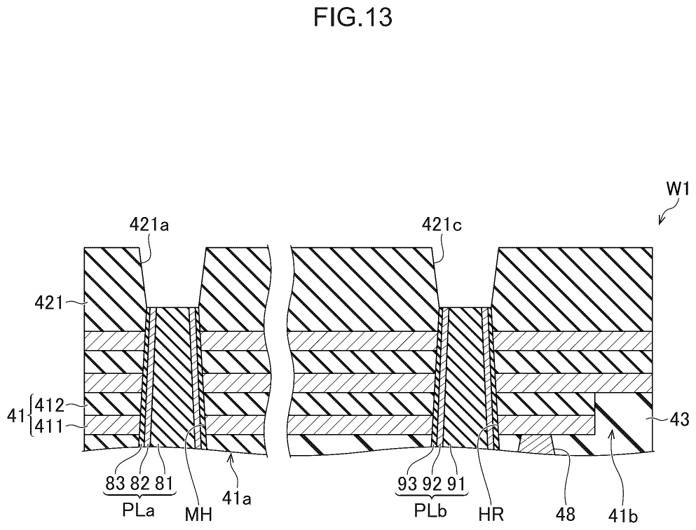

Subsequently, the insulating layer 421, the upper end part of the column-shaped part PLa, and the upper end part of the column-shaped part PLb are fabricated in the Z direction by performing etching back or the like on the upper surface of the first wafer W1 illustrated in FIG. 12. Accordingly, as illustrated in FIG. 13, the gate insulating film 83 and the semiconductor layer 82, which are provided at the upper end part of the column-shaped part PLa, are removed and the core part 81 of the column-shaped part PLa is exposed in the hole 421a of the first wafer W1. Similarly, the gate insulating film 93 and the semiconductor layer 92, which are provided at the upper end part of the column-shaped part PLb, are removed and the core part 91 of the column-shaped part PLb is exposed in the hole 421c of the first wafer W1.

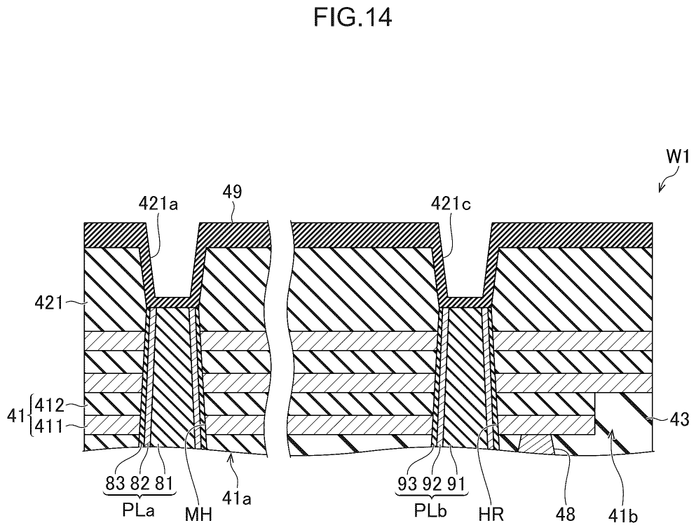

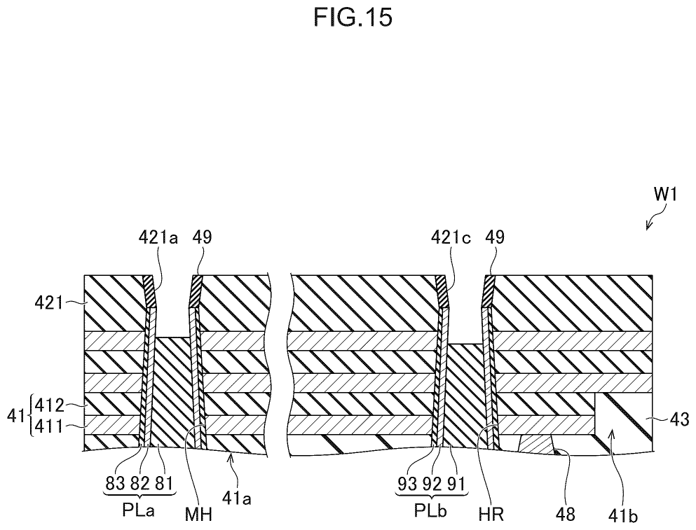

Subsequently, the insulating layer 49 is formed on the upper surface of the first wafer W1 by chemical vapor deposition (CVD) or the like as illustrated in FIG. 14. Thereafter, reactive ion etching (RIE) or the like is performed on the upper surface of the first wafer W1 illustrated in FIG. 14 to remove the insulating layer 49 and also remove the upper end part of the core part 81 of the column-shaped part PLa and the upper end part of the core part 91 of the column-shaped part PLb. Accordingly, the hole 421a is formed to extend to the inside of the upper end part of the column-shaped part PLa as illustrated in FIG. 15. In addition, the hole 421c is formed to extend to the inside of the upper end part of the column-shaped part PLb. Part of the insulating layer 49, which cannot be removed by the RIE remains on the inner peripheral surface at an upper part of each of the holes 421a and 421c.

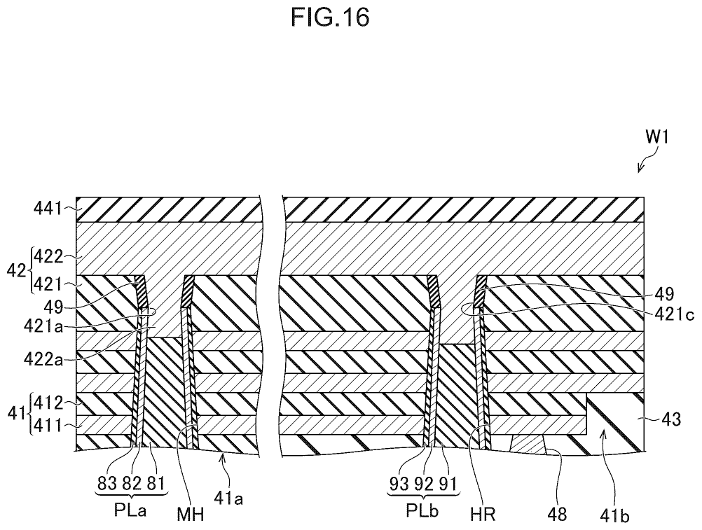

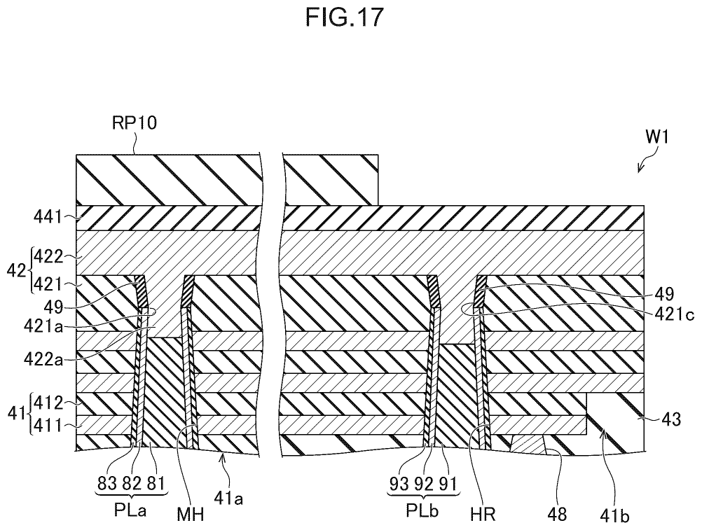

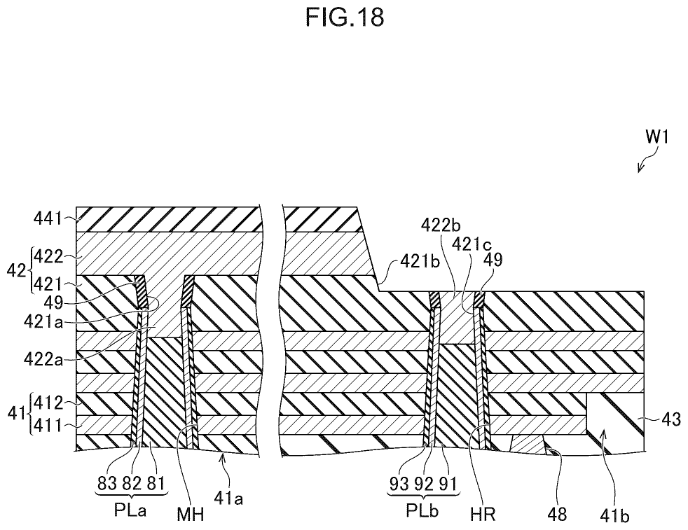

Subsequently, the conductive layer 422 and the insulating layer 441 are sequentially formed on the upper surface of the first wafer W1 by CVD or the like as illustrated in FIG. 16. In this case, part of the conductive layer 422 is embedded in the part of the column-shaped part PLa, from which the core part 81 is removed and the part of the column-shaped part PLb, from which the core part 91 is removed. Thereafter, as illustrated in FIG. 17, a resist pattern RP10 is formed at a part of the upper surface of the first wafer W1, which is positioned above the memory hole MH by a photo engraving process (PEP) or the like. Thereafter, the upper surface of the first wafer W1 is removed by RIE or the like using the resist pattern RP10 as a mask. Accordingly, part of the insulating layer 441, the conductive layer 422, and the insulating layer 421 disposed at a part of the upper surface of the first wafer W1, which is positioned above the column-shaped hole HR is removed as illustrated in FIG. 18. As a result, the recessed part 421b is formed in the insulating layer 421, and the conductive layer 422b and the insulating layer 49 remaining above the column-shaped part PLb are exposed at the bottom surface of the recessed part 421b.

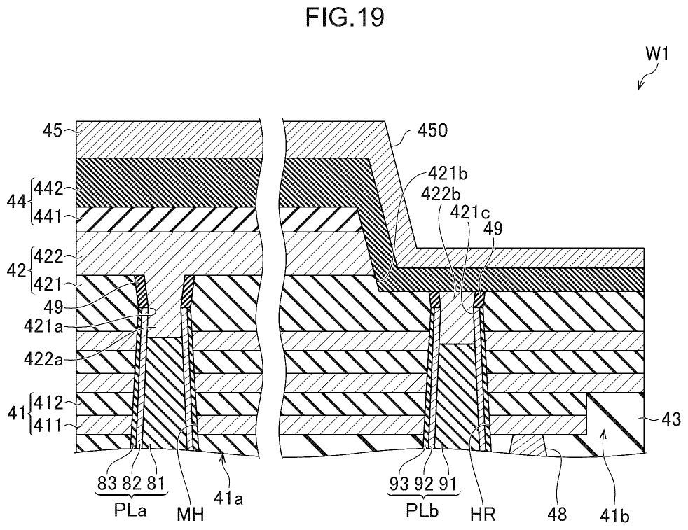

Subsequently, the insulating layer 442 and the conductive layer 45 are sequentially formed on the upper surface of the first wafer W1 by CVD or the like as illustrated in FIG. 19. Accordingly, the first wafer W1 is formed in the same shape as the array part 40 illustrated in FIG. 7.

### 1.5 Effect

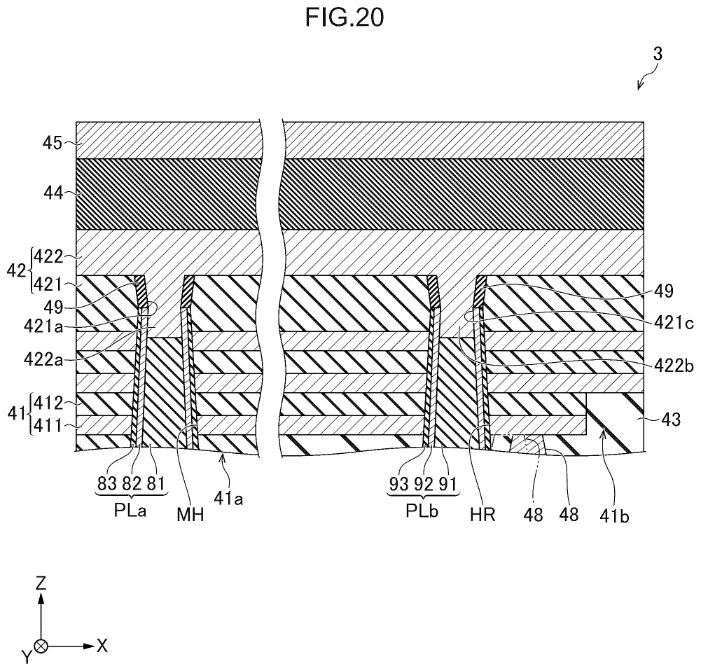

In a semiconductor device 3 of a comparative example illustrated in FIG. 20, the upper end part of the column-shaped part PLb is electrically connected to the conductive layer 422. In a process of manufacturing such a semiconductor device 3, when the position of a column-shaped hole HR is shifted as illustrated with dashed and double-dotted lines in the drawing, the column-shaped part PLb formed in the column-shaped hole HR may directly contact with a contact 48. The same problem also occurs when the position of the contact 48 is shifted. In such a case, the contact 48 may be electrically connected to the conductive layer 422 through the gate insulating film 93 and the semiconductor layer 92 of the column-shaped part PLb, and as a result the contact 48 and the conductive layer 422 may be electrically short-circuited. This can cause defects in the operation of the semiconductor device 3 or the like.

In this respect, in the semiconductor device 2 of the present embodiment, the upper end part of the column-shaped part PLb is electrically insulated from the conductive layer 422 as illustrated in FIG. 7. With such a configuration, even if the column-shaped part PLb directly contacts the contact 48, the contact 48 is not electrically short-circuited to the conductive layer 422 through the gate insulating film 93 and the semiconductor layer 92 of the column-shaped part PLb. Thus, the semiconductor device 2 in which electrical short-circuit is unlikely to occur can be achieved. Moreover, when electrical short-circuit is unlikely to occur, the contact 48 and the column-shaped part PLb can be more closely disposed, which allows integration of the semiconductor device 2. This enables, for example, downsizing of the semiconductor device 2. In addition, the size of the column-shaped part PLb can be increased and thus, for example, the strength of the staircase part 41b can be improved.

The conductive layer 422 is formed at a part above the stacked body 41 except for a part above the column-shaped part PLb. The upper end part of the column-shaped part PLb is spaced apart from the conductive layer 422, and therefore, electrically insulated from the conductive layer 422. The semiconductor device 2 further includes the insulating layer 44 formed above the conductive layer 422, and the conductive layer 45 formed above the insulating layer 44. The upper end of the column-shaped part PLb is in contact with the insulating layer 44. Specifically, an upper end part of at least one of the semiconductor layer 82 and the electric charge accumulation film 832 of the column-shaped part PLb is in contact with the insulating layer 44.

With this configuration, the upper end part of the column-shaped part PLb can be easily insulated from the conductive layer 422.

### 2 Second Embodiment

The following describes a second embodiment of the semiconductor device 2. The description is mainly made on difference from the semiconductor device 2 of the first embodiment.

### 2.1 Structure of Semiconductor Device

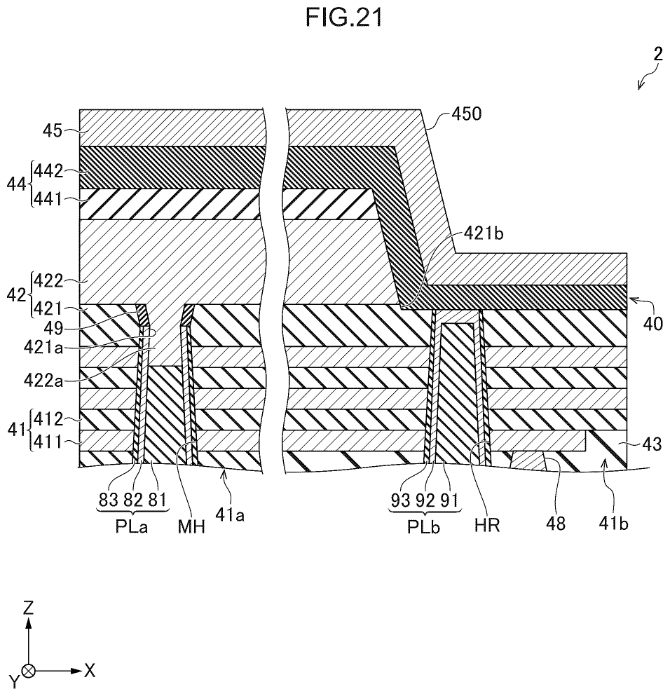

FIG. 21 illustrates a sectional structure of the semiconductor device 2 of the present embodiment. As illustrated in FIG. 21, in the semiconductor device 2 of the present embodiment, an upper end part of the semiconductor layer 92 of the column-shaped part PLb is exposed at the bottom surface of the recessed part 421b of the insulating layer 421. The upper end part of the semiconductor layer 92 is in contact with the insulating layer 44. Thus, the semiconductor device 2 of the present embodiment illustrated in FIG. 21 is different from the semiconductor device 2 of the first embodiment illustrated in FIG. 7 in that no conductive layer 422b is disposed between the upper end part of the core part 91 of the column-shaped part PLb and the insulating layer 44 and no insulating layer 49 is formed on the inner peripheral surface of the hole 421c.

### 2.2 Semiconductor Device Manufacturing Method

The following describes the method of manufacturing the semiconductor device 2 of the present embodiment.

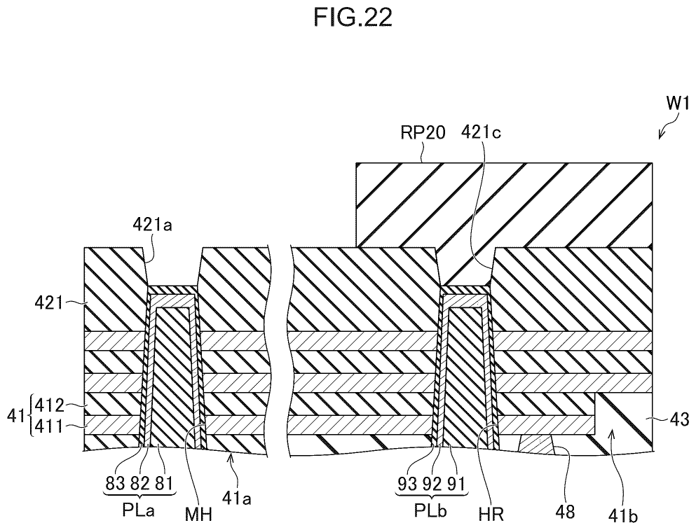

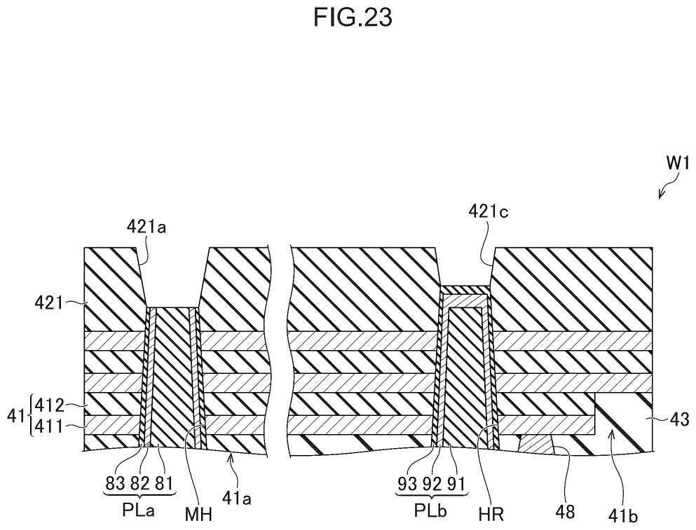

In the semiconductor device 2 of the present embodiment, after the insulating layer 421 is exposed at the upper surface of the first wafer W1 as illustrated in FIG. 12, a resist pattern RP20 is formed at a part of the upper surface of the first wafer W1, which is positioned above the column-shaped hole HR as illustrated in FIG. 22 by PEP or the like. Thereafter, the insulating layer 421 and the upper end part of the column-shaped part PLa are fabricated in the Z direction as illustrated in FIG. 23 by removing the upper surface of the first wafer W1 by RIE or the like using the resist pattern RP20 as a mask. Accordingly, the gate insulating film 83 and the semiconductor layer 82 provided at the upper end part of the column-shaped part PLa are removed and the core part 81 of the column-shaped part PLa is exposed in the hole 421a of the first wafer W1. In contrast, only the insulating layer 421 is removed at the part above the column-shaped part PLb, and therefore, the gate insulating film 93 of the column-shaped part PLb is exposed in the hole 421c of the first wafer W1.

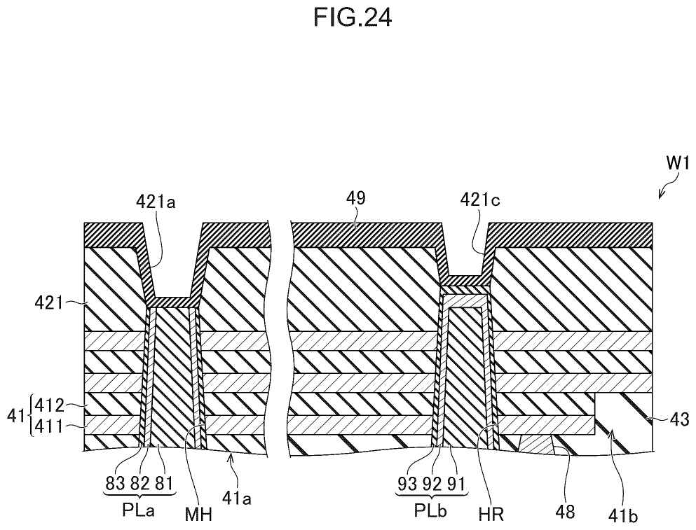

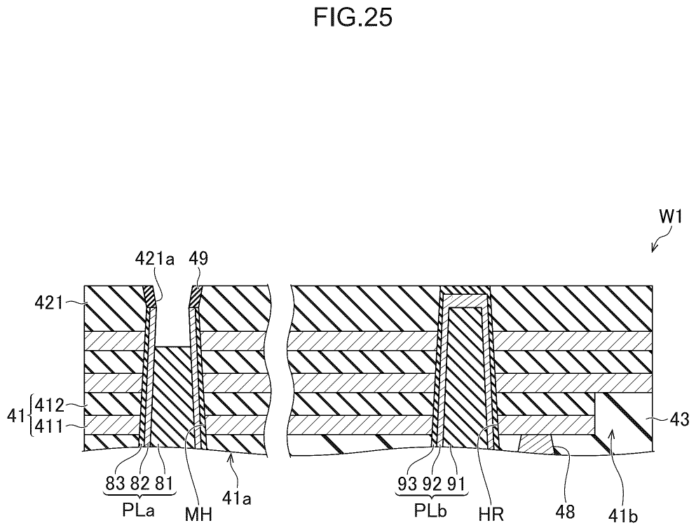

Subsequently, the insulating layer 49 is formed on the upper surface of the first wafer W1 by CVD or the like as illustrated in FIG. 24. Thereafter, the insulating layer 49 is removed by performing RIE or the like on the upper surface of the first wafer W1. In addition, only the upper end part of the core part 81 of the column-shaped part PLa is selectively removed without removing the core part 91 of the column-shaped part PLb. Accordingly, the gate insulating film 93 of the column-shaped part PLb is exposed at the surface of the insulating layer 421 as illustrated in FIG. 25. In addition, the hole 421a extending to the inside of the upper end part of the column-shaped part PLa is formed. Part of the insulating layer 49, which could not be removed by the RIE, remains on the inner peripheral surface of the upper end part of the hole 421c. In this manner, only the upper end part of the column-shaped part PLa is selectively removed in the present embodiment.

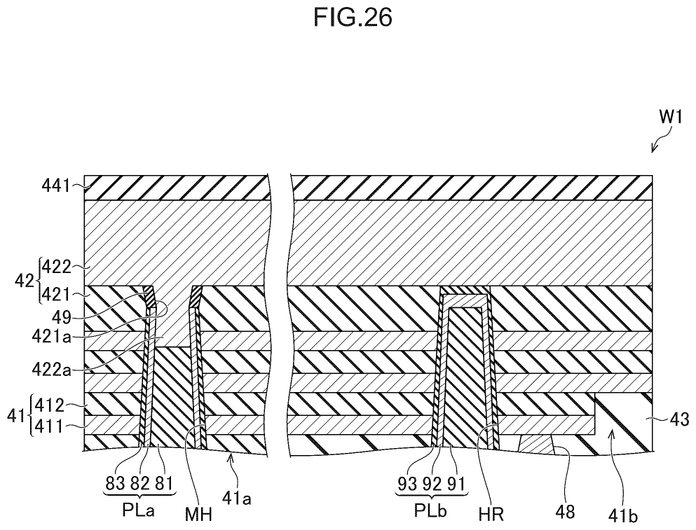

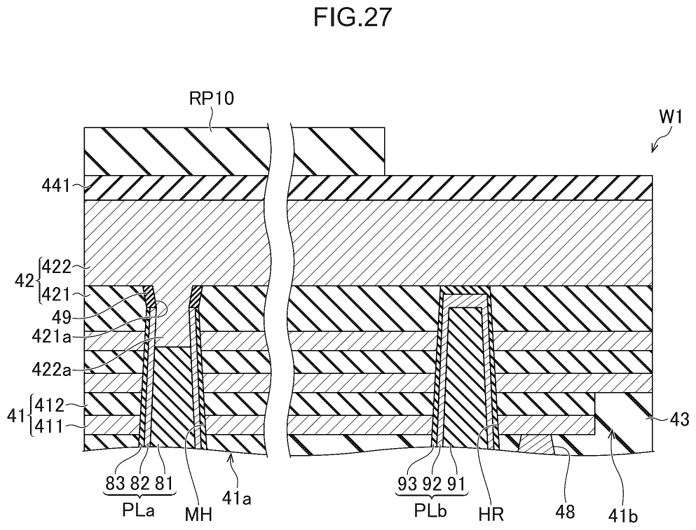

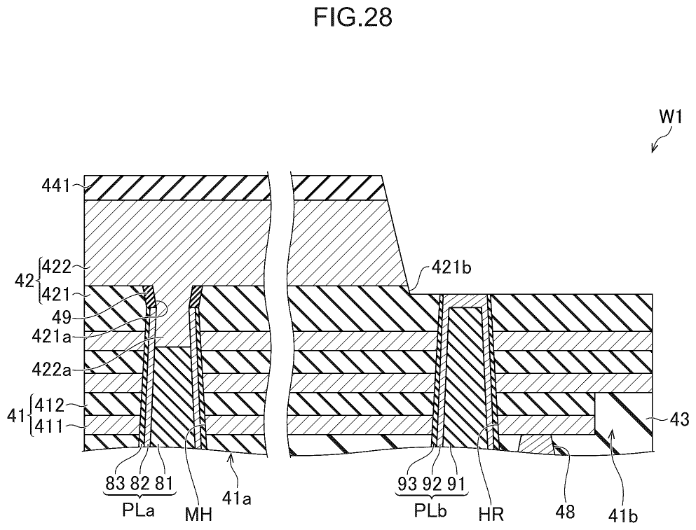

Subsequently, the conductive layer 422 and the insulating layer 441 are sequentially formed on the upper surface of the first wafer W1 by CVD or the like as illustrated in FIG. 26. In this case, part of the conductive layer 422 is embedded in a part of the column-shaped part PLa, from which the core part 81 is removed. Thereafter, the resist pattern RP10 is formed at a part of the upper surface of the first wafer W1, which is positioned above the memory holes MH, by PEP or the like as illustrated in FIG. 27. Then, the upper surface of the first wafer W1 is removed by RIE or the like using the resist pattern RP10 as a mask. Accordingly, part of the insulating layer 441, the conductive layer 422, and the insulating layer 421 disposed at the part of the upper surface of the first wafer W1, which is positioned above the column-shaped holes HR, is removed as illustrated in FIG. 28. As a result, the recessed part 421b is formed at the insulating layer 421, and the gate insulating film 93 of the column-shaped part PLb is exposed at the bottom surface of the recessed part 421b.

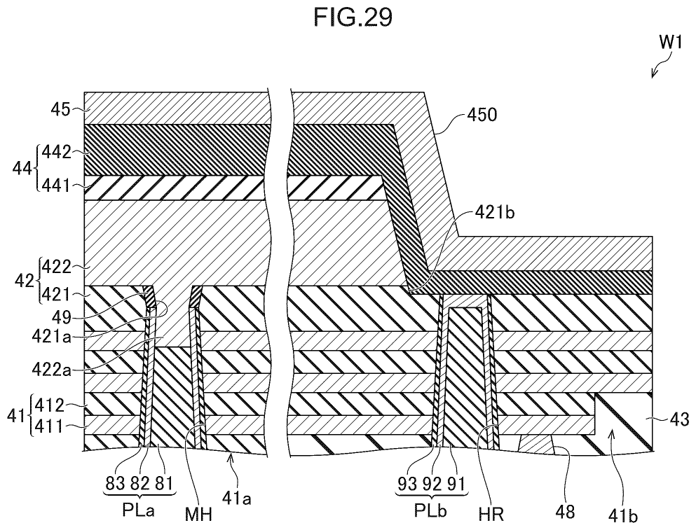

Subsequently, the insulating layer 442 and the conductive layer 45 are sequentially formed on the upper surface of the first wafer W1 by CVD or the like as illustrated in FIG. 29. Accordingly, the first wafer W1 is formed in the same shape as the array part 40 illustrated in FIG. 21.

### 2.3 Effect

The operation of the semiconductor device 2 is not interfered even if the conductive layer 422b is provided between the upper end part of the core part 91 of the column-shaped part PLb and the insulating layer 442 as in the semiconductor device 2 of the first embodiment illustrated in FIG. 7. However, the conductive layer 422b may be electrically connected to another part, which may cause unintended electrical short-circuit.

In this respect, in the semiconductor device 2 of the present embodiment, no conductive layer 422b is provided between the upper end part of the core part 91 of the column-shaped part PLb and the insulating layer 442. Thus, it is possible to prevent unintended electrical short-circuit through the conductive layer 422b.

### 3 Third Embodiment

The following describes a third embodiment of the semiconductor device 2. The description is mainly made on difference from the semiconductor device 2 of the first embodiment.

### 3.1 Structure of Semiconductor Device

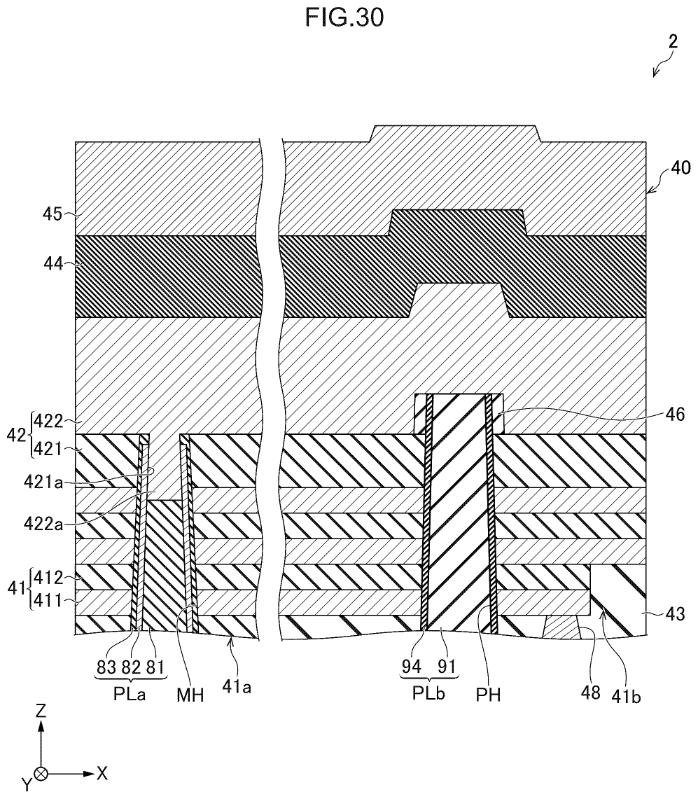

FIG. 30 illustrates a sectional structure of the semiconductor device 2 of the present embodiment. As illustrated in FIG. 30, the column-shaped part PLb of the present embodiment is provided to protrude from the upper surface of the insulating layer 421. The column-shaped part PLb includes the core part 91 and an insulating film 94. The insulating film 94 is formed in a cylindrical shape and provided to enclose the outer periphery of the core part 91. The insulating film 94 is formed of, for example, highly crystalline silicon oxide. The insulating film 94 is disposed between the core part 91 and the conductive layer 411. In the present embodiment, the core part 91 corresponds to a second core part.

An insulating layer 46 is provided on the outer periphery of a part of the column-shaped part PLb, which protrudes from the upper surface of the insulating layer 421. The insulating layer 46 is formed of, for example, silicon oxide.

In the semiconductor device 2 of the present embodiment, the conductive layer 422, the insulating layer 44, and the conductive layer 45 are stacked above the column-shaped part PLb.

### 3.2 Semiconductor Device Manufacturing Method

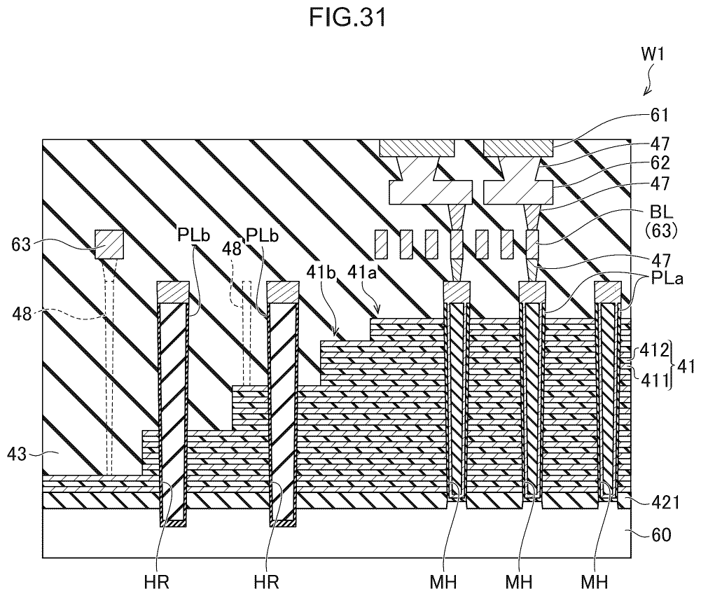

The following describes a method of manufacturing the semiconductor device 2 of the present embodiment. In manufacturing of the semiconductor device 2 of the present embodiment, the first wafer W1 illustrated in FIG. 31 is manufactured. As illustrated in FIG. 31, in the first wafer W1, each column-shaped part PLb is formed to extend to the inside of the substrate 60.

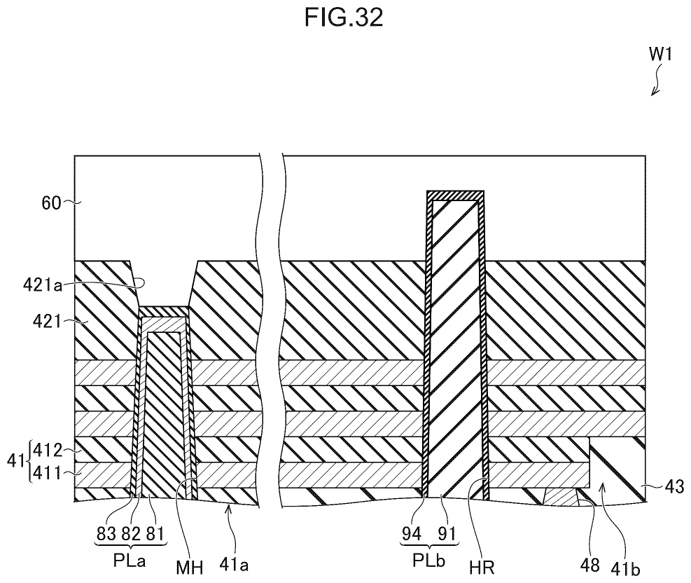

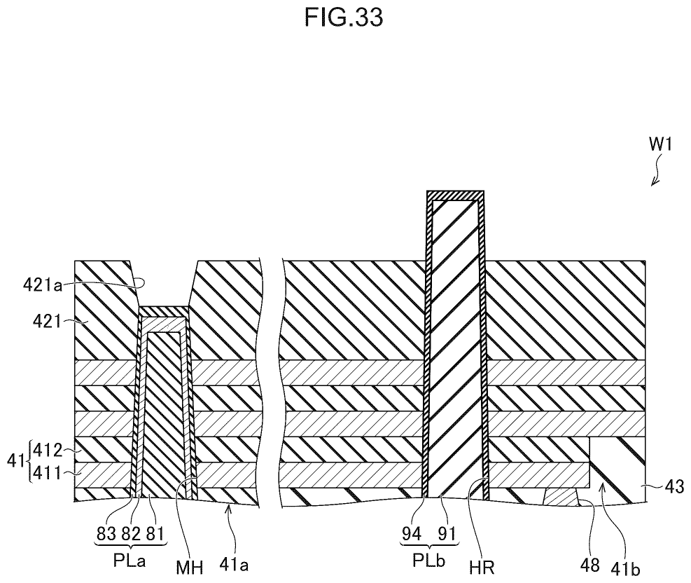

Thereafter, the first wafer W1 and the second wafer W2 are bonded together such that the upper surface of the first wafer W1 is in a state illustrated in FIG. 32. Subsequently, the substrate 60 of the first wafer W1 is removed by wet etching or the like as illustrated in FIG. 33. Accordingly, the insulating layer 421 is exposed at the upper surface of the first wafer W1. In addition, the upper end surface of the column-shaped part PLa is exposed in the hole 421a of the insulating layer 421. Furthermore, the end part of the column-shaped part PLb is disposed to protrude from the upper surface of the insulating layer 421.

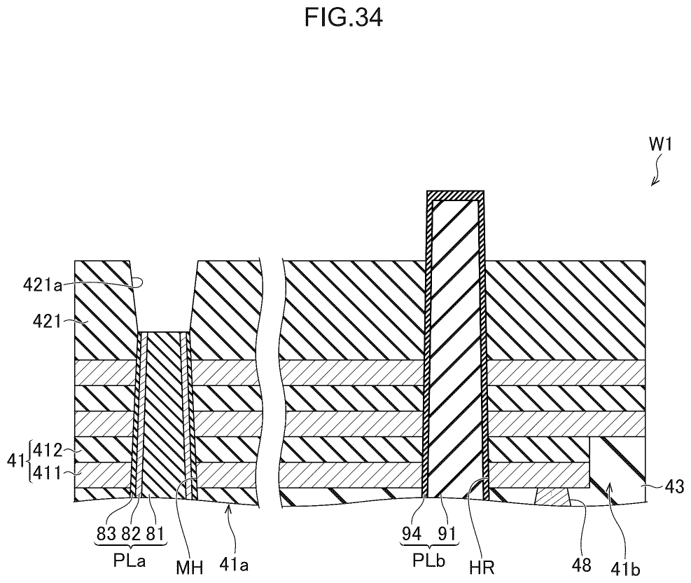

Subsequently, the upper end part of the column-shaped part PLa is fabricated in the Z direction by performing etching back or the like on the upper surface of the first wafer W1 illustrated in FIG. 33. Accordingly, as illustrated in FIG. 34, the gate insulating film 83 and the semiconductor layer 82 provided at the upper end part of the column-shaped part PLa are removed and the core part 81 of the column-shaped part PLa is exposed in the hole 421a of the first wafer W1.

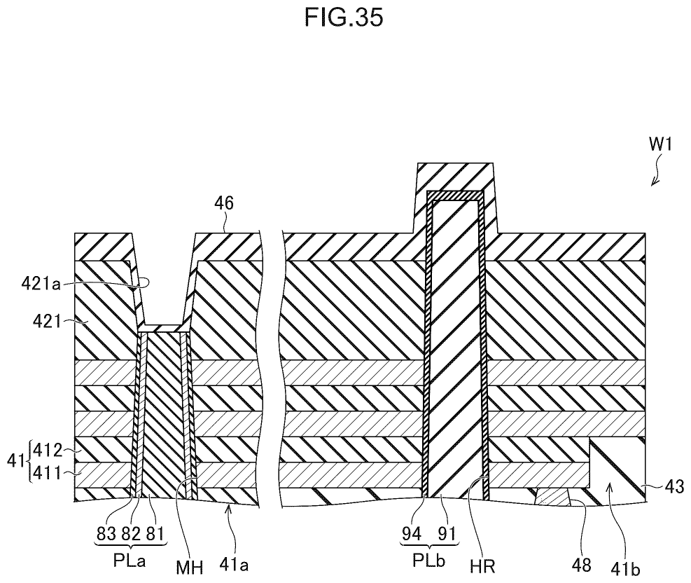

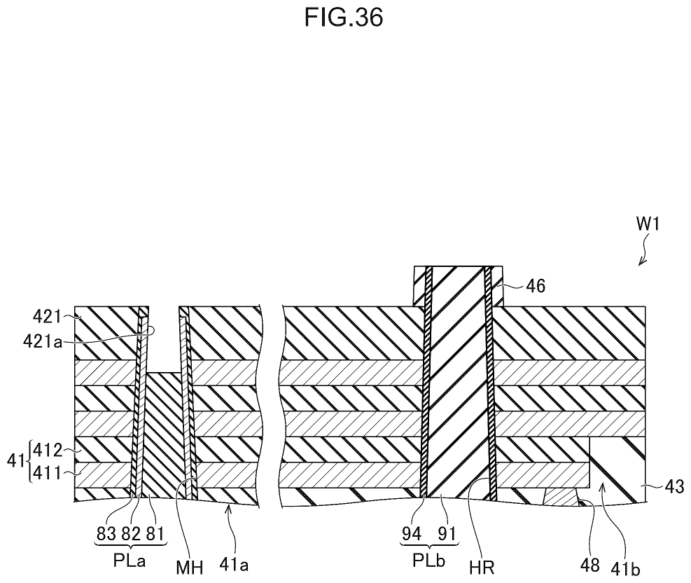

Subsequently, the insulating layer 46 is formed on the upper surface of the first wafer W1 by CVD or the like as illustrated in FIG. 35. Thereafter, RIE or the like is performed on the upper surface of the first wafer W1 illustrated in FIG. 35 to remove the insulating layer 46 and also remove the upper end part of the core part 81 of the column-shaped part PLa and the upper end part of the column-shaped part PLb. Accordingly, the hole 421a is formed to extend to the inside of the upper end part of the column-shaped part PLa as illustrated in FIG. 36. In addition, the core part 91 is exposed at the upper surface of the column-shaped part PLb. Part of the insulating layer 46 remains on the outer periphery of the upper end part of the column-shaped part PLb, which is disposed to protrude from the upper surface of the first wafer W1.

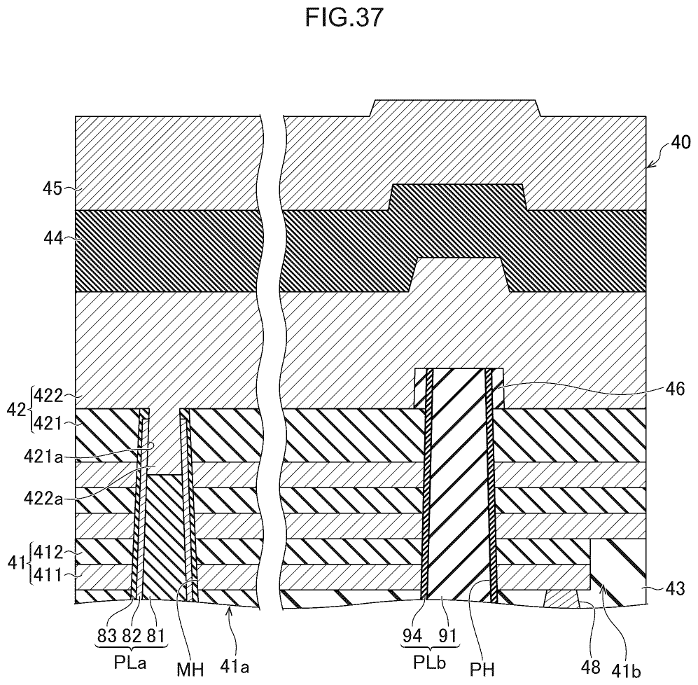

Subsequently, the conductive layer 422, the insulating layer 44, and the conductive layer 45 are sequentially formed on the upper surface of the first wafer W1 by CVD or the like as illustrated in FIG. 37. As a result, the first wafer W1 is formed in the same shape as the array part 40 illustrated in FIG. 30.

### 3.3 Effect

In the semiconductor device 2 of the present embodiment, the column-shaped part PLb includes the core part 91 formed to extend in the Z direction, and the insulating film 94 provided between the conductive layer 411 and the core part 91. With this configuration, even if the column-shaped part PLb directly contacts the contact 48, the contact 48 is not electrically connected to the conductive layer 422 through the column-shaped part PLb. Thus, the semiconductor device 2 in which electrical short-circuit is unlikely to occur can be achieved.

### 4 Other Embodiments

The present disclosure is not limited to the above-described specific examples. For example, each memory cell transistor MT is not limited to a MONOS type but may be a floating gate (FG) type in which a silicon film or the like is used for the electric charge accumulation film 832.

The above-described embodiments of the present invention are presented as examples only and not intended to limit the scope of the invention. These novel embodiments may be performed in other various forms and provided with various kinds of omission, replacement, and change without departing from the subject matter of the invention. These embodiments and their modifications are included in the scope and the subject matter of the invention as well as the scope of the invention described in the claims.

What is claimed is:

1. A semiconductor device comprising:
a first chip including a peripheral circuit; and
a second chip including an array structure of memory cell transistors and bonded to the first chip, wherein
the second chip includes
a stacked body including a memory part and a staircase part, the memory part including a plurality of first conductive layers and a plurality of first insulating layers alternately stacked in a first direction, the staircase part being a part at which end parts of the plurality of first conductive layers are formed in a stepped shape,
a contact connected to the staircase part,
a first column-shaped part formed to extend through the memory part in the first direction and forming a memory cell transistor at an intersection part with the first conductive layer,
a second conductive layer formed above the stacked body and connected to an upper end part of the first column-shaped part, and
a second column-shaped part formed to extend through the staircase part in the first direction, and
the second column-shaped part is electrically insulated from the second conductive layer.

2. The semiconductor device according to claim 1, wherein the second conductive layer contains a metallic material.

3. The semiconductor device according to claim 2, wherein
the first column-shaped part includes
a first core part formed to extend in the first direction and formed of an insulator,
a semiconductor layer provided between the first core part and the first conductive layer, and
an electric charge accumulation film provided between the semiconductor layer and the first conductive layer, and
the semiconductor layer and the second conductive layer are Schottky-joined with each other.

4. The semiconductor device according to claim 3, wherein the second column-shaped part has a same structure as the first column-shaped part.

5. The semiconductor device according to claim 4, wherein
the second conductive layer is formed at a part above the stacked body except for a part above the second column-shaped part, and
an upper end part of the second column-shaped part is spaced apart from the second conductive layer and electrically insulated from the second conductive layer.

6. The semiconductor device according to claim 5, further comprising:
a second insulating layer formed above the second conductive layer; and
a fourth conductive layer formed above the second insulating layer, wherein
the upper end part of the second column-shaped part is in contact with the second insulating layer.

7. The semiconductor device according to claim 6, wherein an upper end part of at least one of the semiconductor layer and the electric charge accumulation film of the second column-shaped part is in contact with the second insulating layer.

8. The semiconductor device according to claim 6, wherein part of the second conductive layer is provided between an upper end part of the first core part and the second insulating layer.

9. The semiconductor device according to claim 6, wherein the second conductive layer is not provided between an upper end part of the first core part and the second insulating layer.

10. The semiconductor device according to claim 3, wherein the second column-shaped part includes
a second core part formed to extend in the first direction, and
an insulating film provided between the first conductive layer and the second core part.

11. A semiconductor device manufacturing method comprising:
forming a first chip including a peripheral circuit;
forming a stacked body including a memory part and a staircase part, the memory part including a plurality of first conductive layers and a plurality of first insulating layers alternately stacked in a first direction, the staircase part being a part at which end parts of the plurality of first conductive layers are formed in a stepped shape;
forming a contact connected to the staircase part;
forming a first column-shaped part provided to extend through the memory part in the first direction and forming a memory cell transistor at an intersection part with the first conductive layer;
forming a second column-shaped part provided to extend through the staircase part in the first direction;
forming a second chip including the stacked body, the contact, the first column-shaped part, and the second column-shaped part;
bonding the first chip and the second chip together;
forming a second conductive layer above the first column-shaped part and the second column-shaped part; and
removing a part of the second conductive layer, which is disposed above the second column-shaped part.

12. The semiconductor device manufacturing method according to claim 11, wherein
the first column-shaped part and the second column-shaped part each include
a core part formed to extend in the first direction and formed of an insulator,
a semiconductor layer provided between the core part and the first conductive layer, and
an electric charge accumulation film provided between the semiconductor layer and the first conductive layer,
after the first chip and the second chip are bonded together, an upper end part of the core part of each of the first column-shaped part and the second column-shaped part is removed, and
the second conductive layer is formed above the first column-shaped part and the second column-shaped part such that the second conductive layer is embedded in a part from which the core part of each of the first column-shaped part and the second column-shaped part is removed.

13. The semiconductor device manufacturing method according to claim 11, wherein
the first column-shaped part and the second column-shaped part each include
a core part formed to extend in the first direction and formed of an insulator,
a semiconductor layer provided between the core part and the first conductive layer, and
an electric charge accumulation film provided between the semiconductor layer and the first conductive layer,
after the first chip and the second chip are bonded together, only an upper end part of the core part of the first column-shaped part is selectively removed without removing the core part of the second column-shaped part, and
the second conductive layer is formed above the first column-shaped part and the second column-shaped part such that the second conductive layer is embedded in a part from which the core part of the first column-shaped part is removed.

14. A semiconductor device manufacturing method comprising:
forming a first chip including a peripheral circuit;
forming a stacked body including a memory part and a staircase part, the memory part including a plurality of first conductive layers and a plurality of first insulating layers alternately stacked in a first direction, the staircase part being a part at which end parts of the plurality of first conductive layers are formed in a stepped shape;
forming a contact connected to the staircase part;
forming a first column-shaped part provided to extend through the memory part in the first direction and forming a memory cell transistor at an intersection part with the first conductive layer;
forming a second column-shaped part provided to extend through the staircase part in the first direction and including a second core part and an insulating film, the second core part being formed to extend in the first direction and including an insulator, the insulating film being provided between the first conductive layer and the second core part;
forming a second chip including the stacked body, the contact, the first column-shaped part, and the second column-shaped part;
bonding the first chip and the second chip together; and
forming a second conductive layer connected to an upper end part of the first column-shaped part and an upper end part of the second column-shaped part.
